(19) United States
(12) Patent Application Publication
(10) Pub. No.: US 2012/0294072 A1
(43) Pub. Date: Nov. 22, 2012

(54) Phase-Change Memory and a Method of Programming the Same

(75) Inventors: Kok Leong Desmond Loke, Singapore (SG); Hongxin Yang, Singapore (SG); Rong Zhao, Singapore (SG); Weijie Wang, Singapore (SG)

(73) Assignee: Agency for Science, Technology and Research

(21) Appl. No.: 13/474,985

(22) Filed: May 18, 2012

(30) Foreign Application Priority Data
May 19, 2011 (SG) 201103620-9

(51) Int. Cl. G11C 11/00; H01L 45/00

(52) U.S. Cl. 365/163; 257/4; 365/148; 257/E45.001

(57) ABSTRACT

According to embodiments of the present invention, a phase-change memory for storing data is provided. The phase-change memory includes a first dielectric material; a second dielectric material; and a phase-change material sandwiched between the first dielectric material and the second dielectric material, at least one of the first or second dielectric materials being a composite dielectric material having a structure of layers of two or more component materials, wherein the first dielectric material has a lower thermal conductivity than the second dielectric material. Further embodiments relate to a method of programming the phase-change memory.

This application claims the benefit of priority of Singapore patent application No. 201103620-9, filed 19 May 2011, the content of it being hereby incorporated by reference in its entirety for all purposes.

### FIELD OF THE INVENTIONS

Various embodiments relate to a phase-change memory for storing data and a method of programming the phase-change memory.

### BACKGROUND OF THE INVENTIONS

Phase-change random access memory (PCRAM) is one of the leading candidates for next generation nonvolatile memory due to its fast access time, low power consumption and high cycle endurance. Its operation is based on the reversible switching of phase-change materials between the amorphous and crystalline states. However, the amorphization current remains large, making it difficult to integrate PCRAM with small transistors. Challenges also exist to achieve shorter crystallization time, due to the trade-off between the speed and stability of phase-change materials. Achieving multilevel programming is also challenging due to the difficulty obtaining multiple discrete-like resistance levels. Resolving these limitations is of great importance in paving the way for commercialization of PCRAM.

One of the possible effective methods to address the above challenges is to control the thermal conditions in the PCRAM. This may be realized through the diligent design of the dielectric material surrounding the phase-change material. In a lateral-type PCRAM, the dielectric is a key functional material that serves not only to define the active device region, but also to provide thermal and electrical insulation. In spite of its importance, very few dielectric materials such as SiO₂ and Al₂O₂ were studied and employed in the lateral-type PCRAM. This is due to difficulties in finding alternative materials with low thermal conductivities as well as compatibility with other functional materials in the lateral-type PCRAM. Thus, there is a need to provide a phase-change memory for storing data, seeking to address at least the problems mentioned.

### SUMMARY

According to an embodiment, a phase-change memory is provided. The phase-change memory may include a first dielectric material; a second dielectric material; and a phase-change material sandwiched between the first dielectric material and the second dielectric material, at least one of the first or second dielectric materials being a composite dielectric material having a structure of layers of two or more component materials, wherein the first dielectric material has a lower thermal conductivity than the second dielectric material.

According to an embodiment, a method of programming a phase-change memory is provided. The method may include applying an electrical pulse across a first electrode and a second electrode of the phase-change memory to cause at least part of a composite phase-change material to become active thereby establishing a resistance within the composite phase-change material, wherein a level of the resistance is dependent on an electrical characteristic of the electrical pulse.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a schematic block diagram of a phase-change memory, according to various embodiments.

FIG. 2 shows a schematic diagram illustrating a cross-sectional view of a lateral-type PCRAM with SLL dielectric structures, according to various embodiments.

FIG. 3 shows a block diagram illustrating a method of programming a phase-change memory, according to various embodiments.

FIG. 4 shows a schematic diagram illustrating a cross-sectional view of a lateral-type SLL PCRAM, according to various embodiments.

FIG. 5 shows heat distribution simulation maps (on left column) and schematic diagrams on the change of states (on right column) of the multi-level SLL PCRAM of FIG. 4 switched to the (a) low resistance level, (b) medium resistance level and (c) high resistance level, according to various embodiments.

FIG. 6 shows a schematic diagram illustrating a cross-sectional view of a lateral-type SLL PCRAM, according to various embodiments.

FIG. 7 shows a schematic representation of multilevel programming for a lateral-type PCRAM, according to various embodiments.

FIG. 8 shows a schematic diagram illustrating a cross-sectional view of a lateral-type SLL PCRAM, according to various embodiments.

FIG. 9 shows a schematic diagram illustrating a cross-sectional view of a lateral-type SLL PCRAM, according to various embodiments.

FIG. 10 shows a heat distribution simulation map for the lateral-type SLL PCRAM of FIG. 8 or 9 for single-level programming, according to various embodiments.

### DETAILED DESCRIPTION OF THE INVENTIONS

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, logical, and electrical changes may be made without departing from the scope of the invention. The various embodiments are not necessarily mutually exclusive, as some embodiments can be combined with one or more other embodiments to form new embodiments.

Embodiments described in the context of one of the methods or devices are analogously valid for the other method or device.

Similarly, embodiments described in the context of a method are analogously valid for a device, and vice versa.

In the context of various embodiments, the phrase “at least substantially” or “substantially” may include “exactly” and a variance of +/−5% thereof. As an example and not limitations, “A is at least substantially same as B” may encompass embodiments where A is exactly the same as B, or where A may be within a variance of +/−5%, for example of a value, of B, or vice versa.

In the context of various embodiments, the term “about” as applied to a numeric value encompasses the exact value and a variance of +/−5% of the value.

As used herein, the term “and/or” includes any and all combinations of one or more of the associated listed items.

Various embodiments may provide phase-change memory for storing data (e.g. a phase-change random access memory) and a method of programming the same. Various embodiments may further provide a superlattice-like dielectric as a thermal insulator in a lateral-type phase-change random access memory.

Various embodiments may provide superlattice-like (SLL) structures incorporated in the dielectric of the lateral-type PCRAM to control the thermal conditions to achieve low-power, high-speed and multi-level programming at the same time.

Various embodiments may provide a lateral-type PCRAM with superlattice-like (SLL) dielectric layer structure/s sandwiching phase-change layer/s for low-power and high-speed multilevel programming.

Various embodiments may provide a SLL dielectric structure having at least two alternating layers of non-crystalline materials. These SLL dielectric structures may possess lower thermal conductivities than bulk materials with the same composition due to the interface phonon scattering effects.

Various embodiments may provide a SLL dielectric structure with excellent thermal confinement properties capable of reducing the power and increasing the speed of lateral-type PCRAM.

Various embodiments may provide a lateral-type SLL PCRAM made up of dielectric materials with different thermal confinement properties to achieve low-power, high-speed and multi-level programming.

Various embodiments may further provide a lateral-type SLL PCRAM for single-level programming.

FIG. 1 shows a schematic block diagram of a phase-change memory 100, according to various embodiments. The phase-change memory 100 for storing data includes a first dielectric material 102; a second dielectric material 104; and a phase-change material 106 sandwiched between the first dielectric material 102 and the second dielectric material 104, at least one of the first or second dielectric materials 102, 104 being a composite dielectric material having a structure of layers of two or more component materials, wherein the first dielectric material 102 has a lower thermal conductivity than the second dielectric material 104.

In the context of various embodiments, the term “phase-change memory” may refer to a phase-change random access memory (PCRAM or PRAM). A “phase-change memory” may be any memory or RAM that stores data using a resistive (or conductive) element having two different resistance states. For example, phase-change memory may be but is not limited to an ovonic unified memory (OUM) and a chalcogenide RAM (C-RAM).

In an embodiment, the phase-change memory may include a lateral-type memory.

In another embodiment, the phase-change memory may be a random-access memory.

In the context of various embodiments, the term “dielectric” or “dielectric material” refers to a material or a layer of low or even non-electrically conducting properties. A composite dielectric material refers to a dielectric material comprising two or more other dielectric materials. For example, the composite dielectric material may be a superlattice-like (SLL) dielectric/phase-change materials, wherein for the phase-change materials residing within the composite dielectric material may be a flat or thin layer which remains substantially amorphous as it is unable to undergo cystallization.

In an embodiment, the composite dielectric material may include a superlattice-like (SLL) dielectric material.

In various embodiments, the term “structure of layers” may refer but is not limited to a superlattice-like (SLL) structure.

In various embodiments, the structure of layers of the composite dielectric material may include a periodic structure of layers. The term “periodic structure” refers to layers that change periodically, for example, repeated alternating layers.

The term “component material” may refer to any material that may be used to form a composite material. In an embodiment, at least one component material of the composite dielectric material may be non-crystalline.

In various embodiments, the sandwiched phase-change material, for example, the phase-change material 106 may be configured to reversibly switch between a high resistance state and a low resistance state.

In the context of various embodiments, the term “phase-change material” may refer to a material or a layer that can switch between the high resistance state and the low resistance state in response to heat, which in this case may be produced by the passage of an electric current through this material via Joule heating. For example, the high resistance state may refer to an “amorphous” state or a substantially amorphous state, and the low resistance state may refer to a “crystalline” state or a substantially crystalline state. The crystalline state gives a resistance state (or value) different to that of the amorphous state. In general, a phase-change material is at least bistable.

The term “amorphous” refers to a relatively less ordered structure than a single crystal and has detectable characteristics such as higher electrical resistivity than the crystalline state.

Conversely, the term “crystalline” refers to a relatively more ordered structure and has detectable characteristics such as lower electrical resistivity than the amorphous state.

The term “sandwiched between” may interchangeably be referred to as “disposed between” or “placed between” or “positioned between”.

In an embodiment, the first and second dielectric materials 102, 104 may sandwich the phase-change material 106 in a horizontal manner. The horizontal axis may be parallel to a plane of a substrate on which the dielectric materials and phase-change material are disposed.

In the context of various embodiments, the first dielectric material 102 and second dielectric material 104 may include a first composite dielectric material and a first second composite dielectric material, respectively.

In an embodiment, the structure of the first composite dielectric material may include a greater number of layers than the structure of the second composite dielectric material.

In an additional embodiment, the structure of the first composite dielectric material may include a greater number of periods than the structure of the second composite dielectric material. For such a configuration, it should be appreciated that the distribution of periods of the composite dielectric material above and below the phase-change material, for example, the phase-change material 106 may be uneven. As solely for illustrative purposes only and not to be understood as limitations, the number of periods for the structure of the first composite dielectric material may, for example, be 5, 6, 7, or 8 while the number of periods for the structure of the second composite dielectric material may, for example, be 2, 3, or 4. It should be appreciated that the respective number of periods are not limited to the above mentioned values and can be any value as long as the first composite dielectric material exhibits improved (or superior) thermal and electrical insulating properties as compared to the second composite dielectric material. For example, the second composite dielectric material may include Ge₂Sb₂Te₅ and SiO₂, or GeTe and SiO₂, or Ge₂Sb₂Te₅ and HfO₂. However, it should be appreciated that other materials and other combinations of materials may also be used.

In the context of various embodiments, the two or more component materials of the composite dielectric material may include a first component material and a second component material, the first component material having a lower thermal conductivity and a lower electrical resistivity than the second component material.

In an embodiment, the two or more component materials of the composite dielectric material may include a first component material and a second component material, wherein the first component material is configured to thermally isolate the phase-change material and the second component material is configured to electrically isolate the phase-change material. In some embodiments, the term ‘isolate’ may be taken to mean isolate from the surrounding environment, such as, for example, from electronic components positioned adjacent or near the phase-change memory 100.

In an embodiment, the structure of the composite dielectric material may include alternate layers of the first component material and the second component material. In one embodiment, the second component material of the composite dielectric material may be adjacent to the phase-change material 106.

In various embodiments, the first component material of the composite dielectric material may be selected from the group consisting of a phase-change materials or a doped phase-change materials or a low-K dielectric materials; and the second component material of the composite dielectric material includes SiO₂ or a high-k dielectric material.

For example, the phase-change material may include Ge₂Sb₂Te₅. The doped phase-change material may include nitrogen-doped Ge₂Sb₂Te₅. The low-K dielectric material may include carbon-doped SiO₂. The high-k dielectric material may include HfO₂.

In the context of various embodiments, the phase-change material may be a composite phase-change material having a structure of layers of two or more component materials.

In an embodiment, the structure of layers of the composite phase-change material may be a periodic structure of layers.

The terms “structure of layers” and “periodic structure” may be similarly defined as above.

In an additional embodiment, the composite phase-change material may be a superlattice-like (SLL) phase-change material.

In an embodiment, the two or more component materials of the composite phase-change material may include at least two of the following group: a phase-change component material, and a phase-change component material including a dielectric component material.

In an embodiment, the two or more component materials of the composite phase-change material may include a phase-change component material and a phase-change component material including a dielectric component material.

In another embodiment, the two or more component materials of the composite phase-change material may include a phase-change component material and a dielectric component material.

In a further embodiment, the structure of the composite phase-change material may include alternate layers of the phase-change component material and the dielectric component material.

In various embodiments, the phase-change component material may be selected from the group consisting of Ge₂Sb₂Te₅, GeTe, Sb₂Te₃, Sb₇Te₃, nitrogen-doped Sb₇Te₃, Sb₂Te, nitrogen-doped Sb₂Te and GeSb.

In an embodiment, the phase-change material 106, or the phase-change component material of the composite phase-change material, may include at least one of the following group: Ge₂Sb₂Te₅, GeTe, Sb₂Te₃, Sb₇Te₃, nitrogen-doped Sb₇Te₃, Sb₂Te, nitrogen-doped Sb₂Te, GeSb.

In various embodiments, the dielectric component material is selected from the group consisting of SiO₂, a high-K dielectric material such as HfO₂, and a combination thereof.

Various embodiments may provide a phase-change memory 100 further including a substrate, a first electrode and a second electrode, wherein the first and second electrodes are arranged spaced apart on the substrate and the phase-change material 106 is arranged to connect the first and second electrodes together.

As used herein, the term “connect” may refer to being electrically connect or being electrically coupled to.

In various embodiments, the substrate may include SiO₂-on-Si.

In an embodiment, the first and second electrodes may be made of the same conductive material.

In a different embodiment, the first and second electrodes may be made of different conductive materials.

In various embodiments, the conductive material may include W, or TiW, or TiN. It should be appreciated that other conductive materials may be used as long as the phase-change material, for example, the phase-change material 106, can connect the first and second electrodes together.

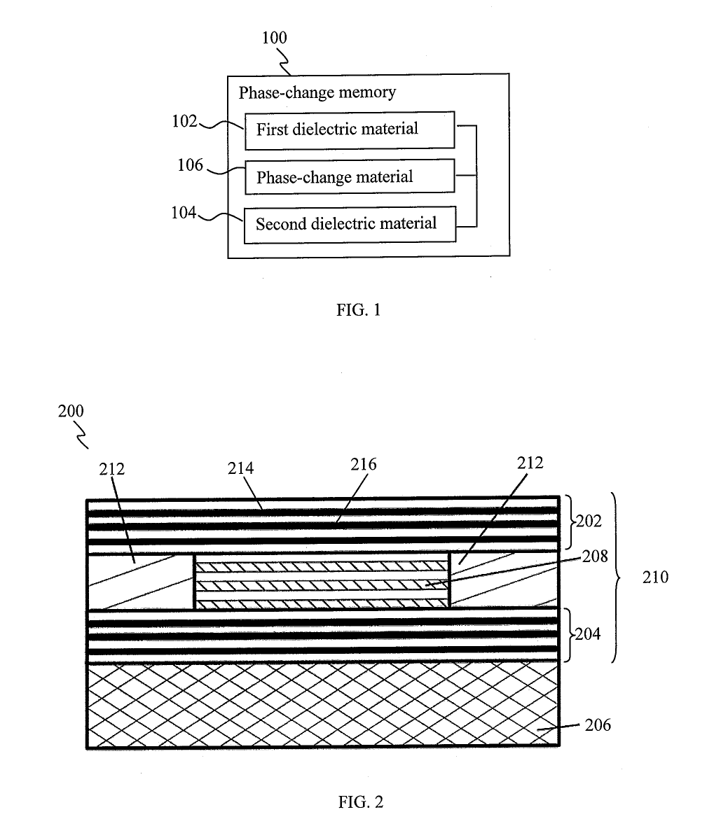

An example of SLL-like structures 202, 204 incorporated in the dielectric of a lateral-type PCRAM 200 to control the thermal conditions to achieve low-power, high-speed and multi-level programming at the same is shown in a cross-sectional view of FIG. 2. The lateral-type PCRAM 200 may include a substrate 206 on which a structure 210 of the dielectric-sandwiched phase-change material 208 is disposed; and a pair of electrodes 212 coupled to the phase-change material 208.

The lateral-type PCRAM 200 of FIG. 2 may refer to the phase-change memory 100 of FIG. 1. The SLL-like structures 202, 204 of FIG. 2 may respective refer to the first and second dielectric materials 102, 104 of FIG. 1. The phase-change material 208 of FIG. 2 may refer to the phase-change material 106 of FIG. 1.

In FIG. 2, each of the SLL dielectric structures 202, 204 includes at least two alternating layers of non-crystalline materials 214, 216. Each SLL dielectric structure 202, 204 possesses lower thermal conductivities than bulk materials with the same composition due to the interface phonon scattering effects.

A SLL dielectric, for example, the SLL dielectric structure 202, 204 of FIG. 2, may be formed with alternate layers of low thermal conductivity materials and dielectric materials such as Ge₂Sb₂Te₅ and SiO₂, respectively. Ge₂Sb₂Te₅ and SiO₂ adhere well to each other and the other functional materials in the PCRAM. Ge₂Sb₂Te₅ has a low thermal conductivity of about 0.3 W/mK, which is about five times lower than that of SiO₂. However, Ge₂Sb₂Te₅ has a low electrical resistivity and is unsuitable as an electrical insulator. On the other hand, SiO₂ is an excellent electrical insulator with a high resistivity. When Ge₂Sb₂Te₅ and SiO₂ are stacked periodically, a SLL dielectric, for example, the SLL dielectric structure 202, 204 of FIG. 2, is formed with thermal and electrical insulating properties that may be superior compared with Ge₂Sb₂Te₅ or SiO₂.

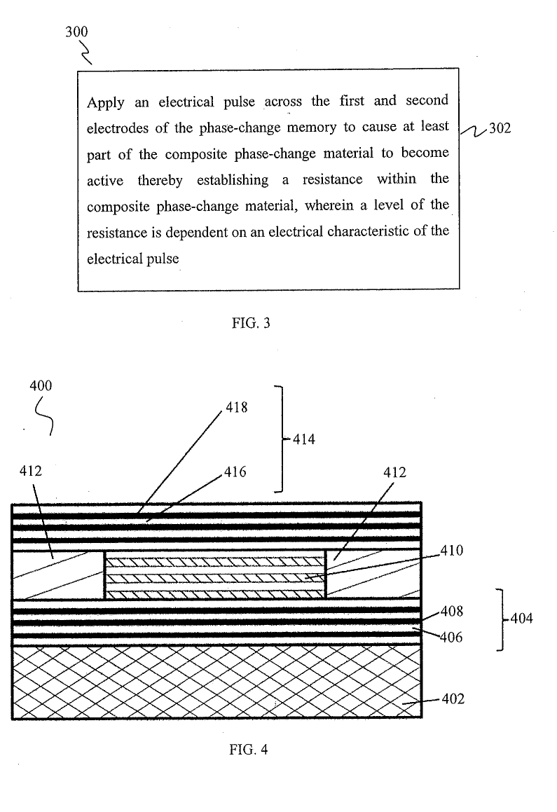

FIG. 3 shows a flow chart illustrating a method of programming a phase-change memory 300, in accordance to various embodiments. The phase-change memory includes a first dielectric material; a second dielectric material; a phase-change material sandwiched between the first dielectric material and the second dielectric material, at least one of the first or second dielectric materials being a composite dielectric material having a structure of layers of two or more component materials; a substrate; a first electrode; and a second electrode, wherein the first and second electrodes are arranged spaced apart on the substrate and the phase-change material is arranged to connect the first and second electrodes together, wherein the first dielectric material has a lower thermal conductivity than the second dielectric material.

At 302, an electrical pulse is applied across the first and second electrodes of the phase-change memory to cause at least part of the composite phase-change material to become active thereby establishing a resistance within the composite phase-change material, wherein a level of the resistance is dependent on an electrical characteristic of the electrical pulse.

In the context of various embodiments, the terms “phase-change memory”, “dielectric” or “dielectric material”, “phase-change material”, “sandwiched”, “composite dielectric material”, “structure of layers” are as defined hereinabove.

As used herein, the term “active” refers to undergoing a phase-change or phase-transformation.

In some embodiments, a part of the composite phase-change material which becomes “active” may include a part which undergoes a phase-change or phase-transformation.

In the context of various embodiments, the term “electric pulse” broadly refers to a voltage or current level being applied to a terminal for a finite time period. The electric pulse may be a unipolar or bipolar pulse.

The term “electrical characteristic” may refer but is not limited to a magnitude and/or a pulse-width. The term “magnitude” refers to a voltage or current amplitude. The term “pulse width” refers to the duration or length of a pulse.

In some embodiments, the electrical characteristic of the electrical pulse may include a magnitude of the electrical pulse and/or a pulse-width of the electrical pulse.

In an embodiment, the level of the resistance may relate to a number of layers of the composite phase-change material which become active when the electrical pulse is applied.

In an embodiment, the method of programming may further include: applying a first electrical pulse across the first and second electrode to establish a first level of resistance within the phase-change memory; and, applying a second electrical pulse across the first and second electrode to establish a second level of resistance within the phase-change memory, the second electrical pulse having a smaller magnitude than the first electrical pulse and the same pulse-width as the first electrical pulse, and the second level of resistance being lower than the first level of resistance.

In another embodiment, the method of programming may further include: applying a third electrical pulse across the first and second electrode to establish a third level of resistance within the phase-change memory, the third electrical pulse having a smaller magnitude and a longer pulse-width than the second electrical pulse, and the third level of resistance being lower than the second level of resistance. It is an advantage of these embodiments that multiple discrete resistance levels may be established in the composite phase-change material by varying characteristics of the electrical pulse.

Various embodiments may provide a lateral-type phase-change random access memory that includes a substrate, two electrodes formed space apart on the substrate, a SLL phase-change layer formed across on the substrate connecting the electrodes and two SLL dielectric layers (where one layer includes materials with lower thermal conductivities compared to those found in the other layer) sandwiching the SLL phase-change layer.

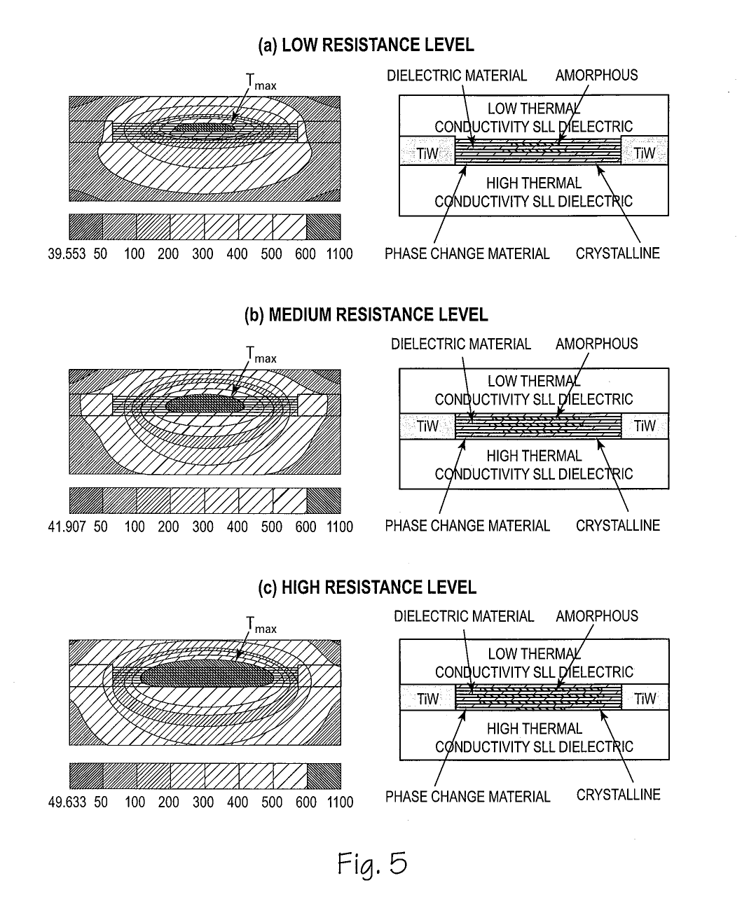

As an illustrative example, FIG. 4 shows a cross-sectional view of the lateral-type PCRAM 400 with SLL dielectric being formed on a substrate 402 of SiO₂-on-Si. This is followed by the deposition of a SLL dielectric layer 404 on the substrate 402. The SLL dielectric layer 404 includes alternating layers of dielectric materials 406 and low thermal conductivity materials 408. The dielectric material 406 may be SiO₂ or high-k dielectric such as HfO₂. The low thermal conductivity material 408 has thermal conductivities lower than the dielectric material and may be phase-change materials such as Ge₂Sb₂Te₅, doped phase-change materials such as nitrogen-doped Ge₂Sb₂Te₅ or low-K dielectric materials such as carbon-doped SiO₂. The phase-change materials should be thin and do not undergo crystallization. Next, a SLL phase-change layer 410 is deposited on the SLL dielectric layer 404. The SLL phase-change layer 410 includes layers with two or more types of (1) phase-change materials or (2) phase-change material and dielectric materials. The phase-change materials may be Ge₂Sb₂Te₅, GeTe, Sb₂Te₃, Sb₇Te₃, nitrogen-doped Sb₇Te₃, Sb₂Te, nitrogen-doped Sb₂Te and GeSb. Dielectric such as SiO₂ or high-k dielectric such as HfO₂ may be used. Following, two electrodes 412 made up of materials such as W, TiW or TiN are formed on each side of the SLL phase-change layer 410. Finally, a low thermal conductivity SLL dielectric layer 414 is formed over the SLL phase-change layer 410. The low thermal conductivity SLL dielectric layer 414 includes alternating layers of dielectric materials 416 and low thermal conductivity materials 418 with lower thermal conductivities compared to those employed in the SLL dielectric layer 404.

The lateral-type PCRAM 400 of FIG. 4 may refer to the phase-change memory 100 of FIG. 1. The SLL dielectric layers 404, 414 of FIG. 4 may respective refer to the first and second dielectric materials 102, 104 of FIG. 1. The phase-change layer 410 of FIG. 4 may refer to the phase-change material 106 of FIG. 1.

In the lateral-type SLL PCRAM, for example, the lateral-type PCRAM 400, a low thermal conductivity SLL dielectric may be paired with a high thermal conductivity SLL dielectric to sandwich a SLL phase-change layer, which functions as an active region. The SLL phase-change layer may include alternating layers of phase-change materials, and dielectric materials. FIG. 5 shows the heat distribution simulation maps (on left column) and schematic diagrams on the change of states (on right column) of the multi-level SLL PCRAM switched to the (a) low resistance level, (b) medium resistance level and (c) high resistance level, in accordance to various embodiments. “Tₘₐₓ” indicates the maximum temperature. When a voltage is applied to the lateral-type SLL PCRAM, the active region would be located closer to the low thermal conductivity SLL dielectric, due to the better thermal confinement of the low thermal conductivity SLL dielectric. The portion of the SLL phase-change layer closer to the low thermal conductivity SLL dielectric will be activated and undergo phase-transformations. Variations in voltage applied to the lateral-type SLL PCRAM would control the number of phase-change material layers activated in the SLL phase-change layer. As seen in FIG. 5, higher resistance is achieved as the number of phase-change layer activated increases. This would enable the lateral-type SLL PCRAM to achieve multiple discrete-like resistance levels.

Various embodiments may provide a lateral-type phase-change random access memory that includes a substrate, two electrodes formed space apart on the substrate, a SLL phase-change layer formed across on the substrate connecting the electrodes and two SLL dielectric layers (where one layer has more SLL periods compared to that of the other layer) sandwiching the SLL phase-change layer.

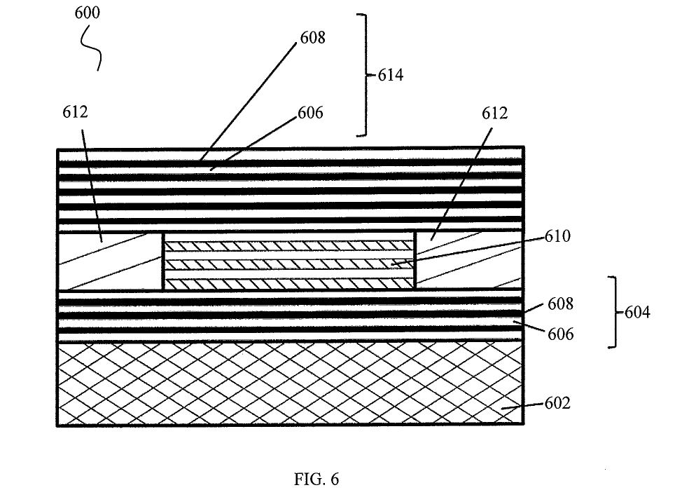

As an illustrative example, FIG. 6 shows a cross-sectional view of the lateral-type PCRAM 600 with SLL dielectric being formed on a substrate 602 of SiO₂-on-Si. This is followed by the deposition of a SLL dielectric layer 604 on the substrate 602. The SLL dielectric layer 604 includes alternating layers of dielectric materials 606 and low thermal conductivity materials 608. The dielectric material 606 can be SiO₂ or high-k dielectric such as HfO₂. The low thermal conductivity material 608 has thermal conductivities lower than the dielectric material and may be phase-change materials such as Ge₂Sb₂Te₅, doped phase-change materials such as nitrogen-doped Ge₂Sb₂Te₅ or low-K dielectric materials such as carbon-doped SiO₂. The phase-change materials should be thin and do not undergo crystallization. Following, a SLL phase-change layer 610 is deposited on the SLL dielectric layer 604. The SLL phase-change layer 610 includes layers with two or more types of (1) phase-change materials or (2) phase-change material and dielectric materials. The phase-change materials may be Ge₂Sb₂Te₅, GeTe, Sb₂Te₃, Sb₇Te₃, nitrogen-doped Sb₇Te₃, Sb₂Te, nitrogen-doped Sb₂Te and GeSb. Dielectric such as SiO₂ or high-k dielectric such as HfO₂ may be used. Next, two electrodes 612 made up of materials such as W, TiW or TiN are formed on each side of the SLL phase-change layer 610. Finally, a high-period SLL dielectric layer 614 is formed over the SLL phase-change layer 610. The high-period SLL dielectric layer 614 has a greater number of SLL periods compared to that of the SLL dielectric layer 604.

The lateral-type PCRAM 600 of FIG. 6 may refer to the phase-change memory 100 of FIG. 1. The SLL dielectric layers 604, 614 of FIG. 6 may respective refer to the first and second dielectric materials 102, 104 of FIG. 1. The phase-change layer 610 of FIG. 6 may refer to the phase-change material 106 of FIG. 1.

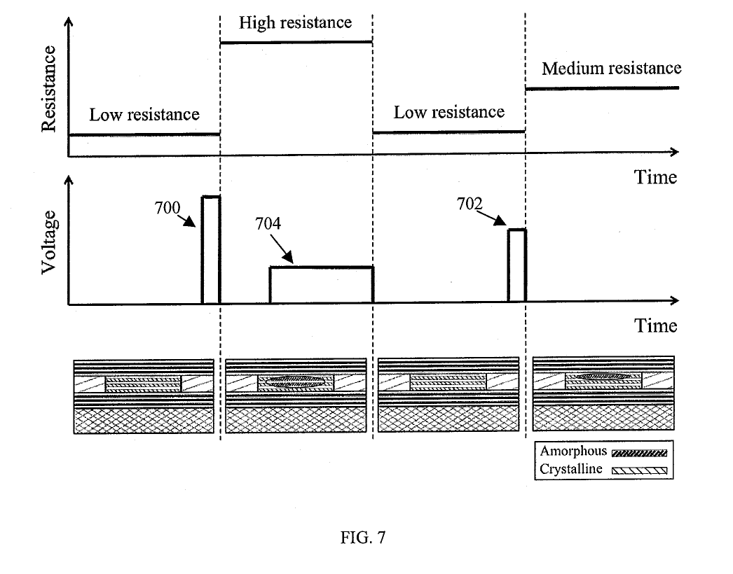

The lateral-type PCRAM 400, 600 (of FIGS. 4 and 6) may be employed for multilevel programming, as shown in the example of FIG. 7. In FIG. 7, the x and y axes of (a) the resistance-time plot and (b) the votage-time plot are of arbitary values. It should be appreciated that the respective plots are used to illustrate a conceptual operation of the lateral-type PCRAM. FIG. 7(c) shows corresponding cross-sectional views of multi-level SLL PCRAM switched to the low resistance level, medium resistance level or high resistance level, in accordance to various embodiments. In the programming cycle, electrical pulses with different pulse conditions were used to achieve three resistance levels. To achieve the high resistance level, a high voltage, short duration reset pulse 700 is employed to switch two layers of materials in the phase-change layer. A medium voltage, short duration reset pulse 702 enables the switching of a layer of material in the phase-change layer to achieve the medium resistance level. To achieve the low resistance level, a low voltage and long duration pulse 704 may be employed to set the PCRAM. Multiple discrete-like resistance levels may be achieved in the lateral-type SLL PCRAM by employing electrical pulses with different amplitudes and/or pulse-widths.

Various embodiments may provide for single-level programming, a lateral-type phase-change random access memory that includes a substrate, two electrodes formed space apart on the substrate, a SLL phase-change layer (made up two or more different materials) formed across on the substrate connecting the electrodes and two SLL dielectric layers sandwiching the SLL phase-change layer.

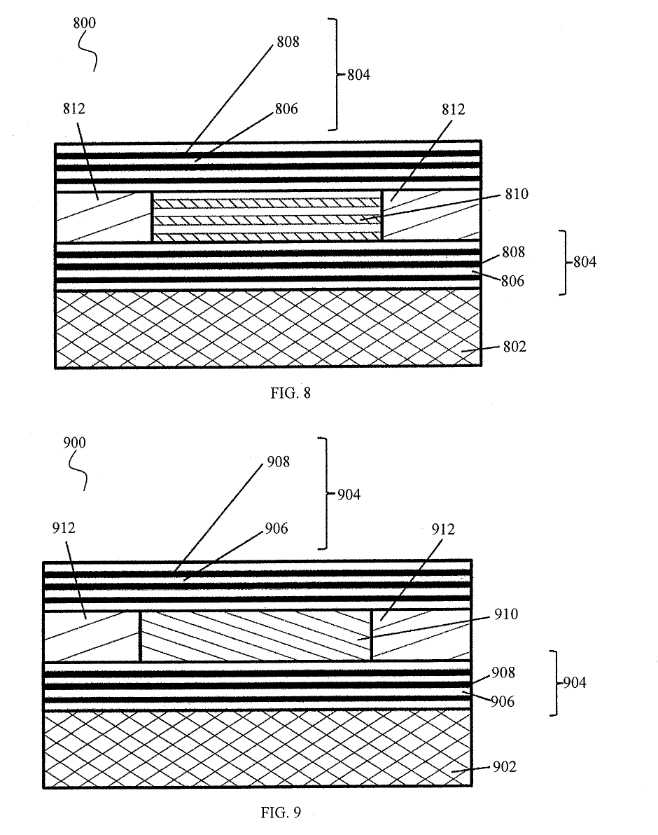

As an illustrative example, FIG. 8 shows a cross-sectional view of the lateral-type PCRAM 800 with SLL dielectric being formed on a substrate 802 comprising of SiO₂-on-Si. This is followed by the deposition of a SLL dielectric layer 804 on the substrate 802. The SLL dielectric layer 804 includes alternating layers of dielectric materials 806 and low thermal conductivity materials 808. The dielectric material 806 may be SiO₂ or high-k dielectric such as HfO₂. The low thermal conductivity material 808 has thermal conductivities lower than the dielectric material and may be phase-change materials such as Ge₂Sb₂Te₅, doped phase-change materials such as nitrogen-doped Ge₂Sb₂Te₅ or low-K dielectric materials such as carbon-doped SiO₂. The phase-change materials should be thin and do not undergo crystallization. Next, a SLL phase-change layer 810 is deposited on the SLL dielectric layer 804. The SLL phase-change layer 810 includes layers with two or more types of (1) phase-change materials or (2) phase-change material and dielectric materials. The phase-change materials may be Ge₂Sb₂Te₅, GeTe, Sb₂Te₃, Sb₇Te₃, nitrogen-doped Sb₇Te₃, Sb₂Te, nitrogen-doped Sb₂Te and GeSb. Dielectric such as SiO₂ or high-k dielectric such as HfO₂ may be used. Following, two electrodes 812 made up of materials such as W, TiW or TiN are formed on each side of the SLL phase-change layer 810. Finally, another SLL dielectric layer 804 is formed over the SLL phase-change layer 810. The SLL dielectric layer 804 includes alternating layers of dielectric materials 806 and low thermal conductivity materials 808. The dielectric material 806 may be SiO₂ or high-k dielectric such as HfO₂. The low thermal conductivity material 808 has thermal conductivities lower than the dielectric material and may be phase-change materials such as Ge₂Sb₂Te₅, doped phase-change materials such as nitrogen-doped Ge₂Sb₂Te₅ or low-K dielectric materials such as carbon-doped SiO₂. The phase-change materials should be thin and do not undergo crystallization.

The lateral-type PCRAM 800 of FIG. 8 may refer to the phase-change memory 100 of FIG. 1. The respective SLL dielectric layers 804 of FIG. 8 may respective refer to the first and second dielectric materials 102, 104 of FIG. 1. The phase-change layer 810 of FIG. 8 may refer to the phase-change material 106 of FIG. 1.

Various embodiments may provide for single-level programming, a lateral-type phase-change random access memory that includes a substrate, two electrodes formed space apart on the substrate, a phase-change layer formed across on the substrate connecting the electrodes and two SLL dielectric layers (made up of alternating layers of low thermal conductivity material and dielectric material) sandwiching the phase-change layer.

As an illustrative example, FIG. 9 shows a cross-sectional view of the lateral-type PCRAM 900 with SLL dielectric being formed on a substrate 902 comprising of SiO₂-on-Si. This is followed by the deposition of a SLL dielectric layer 904 on the substrate 902. The SLL dielectric layer 904 includes alternating layers of dielectric materials 906 and low thermal conductivity materials 908. The dielectric material 906 may be SiO₂ or high-k dielectric such as HfO₂. The low thermal conductivity material 908 has thermal conductivities lower than the dielectric material and may be phase-change materials such as Ge₂Sb₂Te₅, doped phase-change materials such as nitrogen-doped Ge₂Sb₂Te₅ or low-K dielectric materials such as carbon-doped SiO₂. The phase-change materials should be thin and do not undergo crystallization. Next, a phase-change layer 910 made up of materials such as Ge₂Sb₂Te₅, GeTe and Sb₂Te₃ is deposited on the SLL dielectric layer 904. Following, two electrodes 912 made up of materials such as W, TiW or TiN are formed on each side of the phase-change layer 910. Finally, another SLL dielectric layer 904 is formed over the phase-change layer 910. The SLL dielectric layer 904 includes alternating layers of dielectric materials 906 and low thermal conductivity materials 908. The dielectric material 906 may be SiO₂ or high-k dielectric such as HfO₂. The low thermal conductivity material 908 has thermal conductivities lower than the dielectric material and may be phase-change materials such as Ge₂Sb₂Te₅, doped phase-change materials such as nitrogen-doped Ge₂Sb₂Te₅ or low-K dielectric materials such as carbon-doped SiO₂. The phase-change materials should be thin and do not undergo crystallization.

The lateral-type PCRAM 900 of FIG. 9 may refer to the phase-change memory 100 of FIG. 1. The respective SLL dielectric layers 904 of FIG. 9 may respective refer to the first and second dielectric materials 102, 104 of FIG. 1. The phase-change layer 910 of FIG. 9 may refer to the phase-change material 106 of FIG. 1.

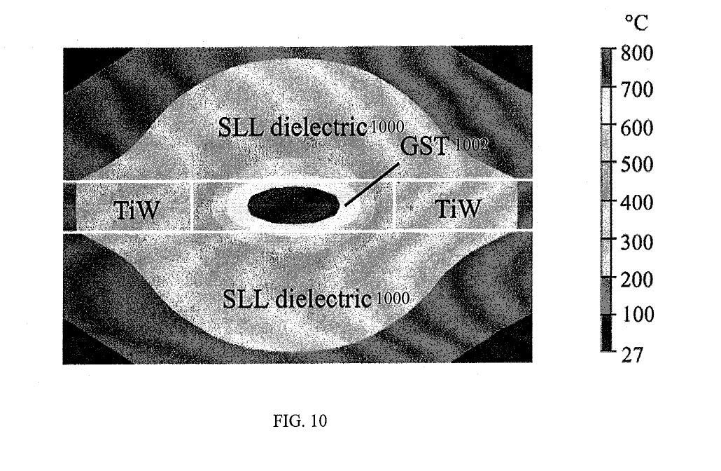

For the lateral-type SLL PCRAM 800, 900, a pair of identical SLL dielectrics with close thermal conductivities is employed to sandwich a SLL or single phase-change layer (as shown in FIGS. 8 and 9 respectively). FIG. 10 shows a heat distribution simulation map of the lateral-type SLL PCRAM for single-level programming. As a voltage is applied to the PCRAM, for example, the lateral-type SLL PCRAM 800, 900 (of FIGS. 8 and 9), the active region would be located in the centre of the SLL phase-change layer, which may be attributed to the similar thermal confinement provided by the pair of SLL dielectrics 1000. The main portion in the centre of the SLL phase-change layer 1002 would undergo phase transitions, which enables the lateral-type SLL PCRAM to achieve either the high or low resistance level.

While the preferred embodiments of the devices and methods have been described in reference to the environment in which they were developed, they are merely illustrative of the principles of the inventions. Other embodiments and configurations may be devised without departing from the spirit of the inventions and the scope of the appended claims.

We claim:

1. A phase-change memory for storing data, the phase-change memory comprising:
a first dielectric material;
a second dielectric material; and
a phase-change material sandwiched between the first dielectric material and the second dielectric material, at least one of the first or second dielectric materials being a composite dielectric material having a structure of layers of two or more component materials,
wherein the first dielectric material has a lower thermal conductivity than the second dielectric material.

2. The phase-change memory of claim 1, wherein the sandwiched phase-change material is configured to reversibly switch between a high resistance state and a low resistance state.

3. The phase-change memory of claim 1, wherein the structure of layers of the composite dielectric material comprises a periodic structure of layers.

4. The phase-change memory of claim 1, wherein the first dielectric material and second dielectric material comprise a first composite dielectric material and a second composite dielectric material, respectively.

5. The phase-change memory of claim 4, wherein the structure of the first composite dielectric material comprises a greater number of periods than the structure of the second composite dielectric material.

6. The phase-change memory of claim 1, wherein the two or more component materials of the composite dielectric material comprise a first component material and a second component material, the first component material having a lower thermal conductivity and a lower electrical resistivity than the second component material.

7. The phase-change memory of claim 6, wherein the first component material of the composite dielectric material is selected from the group consisting of a phase-change material, or a doped phase-change material or a low-K dielectric material;
and the second component material of the composite dielectric material comprises SiO₂ or a high-k dielectric material.

8. The phase-change memory of claim 7, wherein the phase change material comprises Ge₂Sb₂Te₅.

9. The phase-change memory of claim 7, wherein the doped phase-change material comprises nitrogen-doped Ge₂Sb₂Te₅.

10. The phase-change memory of claim 7, wherein the low-K dielectric material comprises carbon-doped SiO₂.

11. The phase-change memory of claim 7, wherein the high-k dielectric material comprises HfO₂.

12. The phase-change memory of claim 1, wherein the phase-change material is a composite phase-change material having a structure of layers of two or more component materials.

13. The phase-change memory of claim 12, wherein the structure of layers of the composite phase-change material is a periodic structure of layers.

14. The phase-change memory of claim 12, wherein the two or more component materials of the composite phase-change material comprise at least two of the following group: a phase-change component material, and a phase-change component material including a dielectric component material.

15. The phase-change memory of claim 14, wherein the phase-change component material is selected from the group consisting of Ge₂Sb₂Te₅, GeTe, Sb₂Te₃, Sb₇Te₃, nitrogen-doped Sb₇Te_{3,} Sb₂Te, nitrogen-doped Sb₂Te and GeSb.

16. The phase-change memory of claim 14, wherein the dielectric component material is selected from the group consisting of SiO₂ and HfO₂.

17. The phase-change memory of claim 1, further comprising a substrate, a first electrode and a second electrode, wherein the first and second electrodes are arranged spaced apart on the substrate and the phase-change material is arranged to connect the first and second electrodes together.

18. The phase-change memory of claim 17, wherein the substrate comprises SiO₂-on-Si.

19. The phase-change memory of claim 17, wherein the first and second electrodes are made of the same conductive material.

20. The phase-change memory of claim 17, wherein the first and second electrodes are made of different conductive materials.

21. The phase-change memory of claim 19, wherein the conductive material comprises W, or TiW, or TiN.

22. A method of programming a phase-change memory, the phase-change memory comprising a first dielectric material; a second dielectric material; a phase-change material sandwiched between the first dielectric material and the second dielectric material, at least one of the first or second dielectric materials being a composite dielectric material having a structure of layers of two or more component materials; a substrate; a first electrode; and a second electrode, wherein the first and second electrodes are arranged spaced apart on the substrate and the phase-change material is arranged to connect the first and second electrodes together, wherein the first dielectric material has a lower thermal conductivity than the second dielectric material,
the method comprising:
applying an electrical pulse across the first and second electrodes of the phase-change memory to cause at least part of the composite phase-change material to become active thereby establishing a resistance within the composite phase-change material, wherein a level of the resistance is dependent on an electrical characteristic of the electrical pulse.

23. The method of claim 22, wherein the sandwiched phase-change material of the phase-change memory is configured to reversibly switch between a high resistance state and a low resistance state.

24. The method of claim 22, wherein the electrical characteristic of the electrical pulse includes a magnitude of the electrical pulse and/or a pulse-width of the electrical pulse.

25. The method of claim 22, wherein the level of the resistance relates to a number of layers of the composite phase-change material which become active when the electrical pulse is applied.
